(19) United States
(12) Patent Application Publication
(10) Pub. No.: US 2025/0015623 A1
(43) Pub. Date: Jan. 9, 2025

(54) Method for Charging or Discharging an Exchangeable Energy Store by Means of an Electrical Device and System Comprising an Exchangeable Energy Store and an Electrical Device for Carrying out the Method

(71) Applicant: Robert Bosch GmbH, Stuttgart (DE)

(72) Inventors: Alexander Osswald, Stuttgart (DE); Christoph Klee, Stuttgart (DE); Marc-Alexandre Seibert, Stuttgart (DE); Holger Wernerus, Pliezhausen (DE)

(21) Appl. No.: 18/710,107

(22) PCT Filed: Nov. 2, 2022
(86) PCT No.: PCT/EP2022/080480

§ 371 Date: May 14, 2024

(30) Foreign Application Priority Data
Nov. 15, 2021 (DE) 10 2021 212 799.1

(51) Int. Cl. H02J 7/00; G01R 31/3835; G01R 31/389

(52) U.S. Cl. CPC H02J 7/007182; G01R 31/3835; G01R 31/389; H02J 7/00036; H02J 7/00043; H02J 7/0045; H02J 7/0047; H02J 7/0063

(57) ABSTRACT

A method for charging or discharging an exchangeable energy store by means of an electrical device includes connecting a first electromechanical interface of the energy store to a further electromechanical interface of the electric device, applying a first measurement signal to a first signal contact or data contact of the further electromechanical interface without a charging or discharging current flowing, detecting a first voltage drop between the first signal contact or data contact and a first power contact of the further electromechanical interface operatively connected to the first signal contact or data contact, applying a charging or discharging current to the power contact of the further electromechanical interface, detecting again a first voltage drop between the first signal contact or data contact and the first power contact of the further electromechanical interface of the electrical device, and calculating a voltage difference between the two detected first voltage drops.

The invention relates to a method for charging or discharging an exchangeable energy store, in particular an exchangeable rechargeable battery pack, by means of an electrical device, in particular a charging device or an electrical load. The invention further relates to a system comprising an electrical energy store and an electrical device for carrying out the method.

### PRIOR ART

A large number of electrical loads are operated with exchangeable energy stores that can be exchanged by the operator via corresponding electromechanical interfaces, which are discharged by the electrical load and can be recharged using a charging device. Such energy stores can consist of one energy storage cell or a plurality of energy storage cells connected in series and/or in parallel to achieve a required battery voltage or capacitance. A particularly advantageous high power and energy density can be achieved if the energy storage cells are, e.g., designed as lithium ion cells (Li-ion).

When charging or discharging the exchangeable energy store, an undesirable voltage drop can occur, in particular at the electrical contacts of the electromechanical interfaces of the exchangeable energy store and the electrical device, which are designed as power contacts, due to any contact resistances, which depends on the respective charging or discharging current. This voltage drop can lead to a distortion of signals provided via corresponding signal contact or data contacts of the electromechanical interfaces in the electrical load or in the charging device in order to determine certain operating parameters of the exchangeable energy store if the signals relate to the potential of a power contact that is operatively connected to it. In addition, increasing wear or soiling of the electrical contacts increases their contact resistance and thus also the resulting voltage drop, which can ultimately impair the function of the electrical device or the exchangeable energy store.

EP 2 051 088 A1 describes a method for determining the internal and connection resistance of a battery, which is intended in particular for the mains supply of a control center and/or a peripheral unit of a hazard alarm system. Furthermore, a circuit arrangement designed as part of a hazard alarm system for determining the internal and connection resistance of the battery is disclosed, wherein the circuit arrangement has an input for connecting the circuit arrangement to the battery, a measuring resistor for loading the battery with a measuring current and a switch for temporarily closing a circuit. If the switch is closed, a measuring current can flow that leads to a temporary load on the measuring resistor with a measuring power that is greater than the nominal power of the measuring resistor.

Based on the prior art, the task of the invention is to improve the charging or discharging process of an exchangeable energy store as a function of the charging or discharging current such that any measurement errors can be compensated for directly and wear or soiling of the electrical contacts of the electromechanical interfaces can be detected at an early stage.

### Advantages of the Invention

To solve the task, a method is provided for charging or discharging an exchangeable energy store, in particular an exchangeable rechargeable battery pack, by means of an electrical device, in particular a charging device or an electrical load, comprising at least the following steps:
a. connecting a first electromechanical interface of the exchangeable energy store to a further electromechanical interface of the electric device,
b. applying a first measurement signal to a first signal contact or data contact of the further electromechanical interface of the electrical device, without a charging or discharging current flowing,
c. detecting a first voltage drop between the first signal contact or data contact and a first power contact of the further electromechanical interface of the electrical device operatively connected to the first signal contact or data contact,
d. additionally, applying a charging or discharging current I to the power contact of the further electromechanical interface of the electrical device,
e. detecting again a voltage drop between the first signal contact or data contact and the first power contact of the further electromechanical interface of the electrical device, and
f. calculating a voltage difference between the voltage drops detected in step c and step e.

Furthermore, a system for carrying out the method is provided, which comprises an electrical energy store, in particular a exchangeable rechargeable battery pack, with a first electromechanical interface having a plurality of electrical contacts and an electrical device, in particular a charging device or an electrical load, with a control or regulation unit and with a further electromechanical interface having a plurality of electrical contacts, wherein, in each case, a first one of the electrical contacts of the electromechanical interfaces is designed as a first signal contact or data contact and, in each case, a second one of the electrical contacts of the electromechanical interfaces is designed as a first power contact to which a first reference potential, preferably a ground potential, can be applied. The electrical device and the exchangeable energy store each have at least one first resistor, which is intended to form a first voltage divider connected to the first power contacts via the signal contact or data contacts when the electromechanical interfaces are connected.

A particular advantage of the method and system according to the invention is that the calculated voltage difference makes it possible to detect electrical contact problems of the electromechanical interfaces at an early stage during the charging or discharging process in order to be able to react accordingly.

Electrical loads in the context of the invention are to be understood as, for example, power tools operated with an energy store designed as an exchangeable rechargeable battery pack for processing workpieces by means of an electrically driven insert tool. The power tool can in this case be designed both as a hand-held power tool, or also as a stationary electric machine tool. A particular advantage is that the exchangeable rechargeable battery pack can be replaced by an operator without tools, i.e. by hand. Typical power tools in this context include hand or bench drills, screwdrivers, percussion drills, drill hammer, planers, angle grinders, orbital sanders, polishing machines, circular saws, table saws, crosscut saws and jigsaws, or the like. However, lights operated with an exchangeable rechargeable battery pack and measuring devices such as rangefinders, leveling devices, wall scanners, etc., garden and construction equipment such as lawn mowers, lawn trimmers, branch saws, tilling and trenching machines, robot breakers and excavators or the like and household appliances such as vacuum cleaners, mixers, etc. can also be considered as electrical loads. The invention is also applicable to electrical loads which can be supplied simultaneously with a plurality of exchangeable rechargeable battery packs in order to achieve a high running time and/or performance. Other possible electrical loads in the context of the invention are road, rail or air vehicles equipped with accumulators or fuel cells whose energy stores can only be replaced by the manufacturer. The exchangeable energy stores can also be designed as non-rechargeable primary cells or similar. In this case, the invention is limited to the discharging process alone.

The voltage of a exchangeable rechargeable battery pack is typically a multiple of the voltage of a single energy storage cell and results from the interconnection (parallel or in series) of the individual energy store cells. An energy storage cell is typically designed as a galvanic cell comprising a structure in which a cell pole comes to rest on one end and another cell pole comes to rest on an opposite end. In particular, the energy storage cell comprises a positive cell pole at one end and a negative cell pole at an opposite end. Preferably, the energy storage cells are formed as lithium-based energy storage cells, e.g., Li-ion, Li-po, Li-metal, or the like. However, the invention can also be applied to exchangeable rechargeable battery packs having Ni—Cd cells, Ni-MH cells, or other suitable cell types. In conventional Li-ion energy storage cells with a cell voltage of 3.6 V, voltage classes result of, e.g., 3.6 V, 7.2 V, 10.8 V, 14.4 V, 18 V, 36 V, etc. Preferably, an energy storage cell is designed as an at least substantially cylindrical round cell, wherein the cell poles are arranged at ends of the cylindrical shape. However, the invention does not depend on the type and design of the energy storage cells used, but can instead be applied to any exchangeable rechargeable battery packs and energy storage cells, e.g. pouch cells or the like, in addition to round cells.

It should also be noted that the embodiment of the electromechanical interfaces of the exchangeable rechargeable battery packs and the electrical devices that can be connected to them, as well as the associated receptacles for non-positively and/or positively detachable connection, are not intended to be the subject of the present invention. A person skilled in the art will select a suitable embodiment for the interface depending on the power or voltage class of the electrical device and/or the exchangeable rechargeable battery packs. The embodiments shown in the drawings are therefore only to be understood by way of example. Thus interfaces having more electrical contacts than illustrated can in particular also be used.

In a further embodiment of the invention, it is provided that the first voltage drop at the first signal contact or data contact is compensated on the basis of the voltage difference calculated in step f. In this way, any measurement error can be avoided, for example by subtracting the voltage difference from the measured voltage drop.

To measure the voltage drop at the first signal contact or data contact, the at least one first resistor of the exchangeable energy store is designed as an invariable resistor, in particular as a coding resistor, or as a variable resistor, in particular as a temperature resistor. Furthermore, the at least one first resistor of the electrical device is designed as an invariable resistor.

If the at least one first resistor of the exchangeable energy store is designed as a coding resistor, the electrical device can determine the maximum charging or discharging current with which the exchangeable energy store may be operated by measuring the voltage drop caused by the coding resistor via the first signal contact or data contacts. For this purpose, a control or regulation unit of the electrical device compares the measured resistance value with a resistance value stored in a look-up table. A first resistor in the form of a temperature resistor enables the electrical device to influence the charging or discharging current as a function of the temperature of the exchangeable energy store. Any voltage difference calculated in step f can be used to detect and compensate for a measurement error which, without corresponding compensation, would lead to an incorrectly set maximum charging or discharging current or to an incorrectly detected temperature in the exchangeable energy store. If the maximum charging or discharging current is too high, this can damage or destroy the exchangeable energy store and possibly also the electrical device connected to it, while a maximum charging or discharging current that is too low reduces the performance of the electrical load or prolongs the charging process using a charging device.

In addition, it may be provided that at least one third electrical contact of the further electromechanical interface of the electrical device, which is designed as a second signal contact or data contact, is subjected to at least one second measurement signal, wherein a second voltage drop is measured at the at least one second signal contact or data contact of the electrical device by means of the at least one second measurement signal and the second voltage drop is compensated by means of the voltage difference calculated in step f. For this purpose, the electrical device and the exchangeable energy store each have at least one second resistor, which are provided to form a second voltage divider connected to the first power contacts via the second signal contact or data contacts when the electromechanical interfaces are connected. In this case, the at least one first resistor of the exchangeable energy store is designed as an invariable resistor, in particular as a coding resistor, and the at least one second resistor of the exchangeable energy store is designed as a variable resistor, in particular as a temperature resistor, whereas the at least one first and the at least one second resistor of the electrical device are each designed as an invariable resistor. The advantage of using a invariable resistor to calculate the voltage difference in step f is that the compensation is independent of gradual changes, for example due to temperature fluctuations. This means that variable measured variables can also be compensated for very well. In principle, however, it is also conceivable to use a variable resistor to calculate the voltage difference in step f, with the corresponding disadvantages. In particular, with a variable resistor designed as a temperature resistor, it can be assumed that the temperature and therefore also the resistance value will not change within a limited time window in which the charging or discharging current is applied to the first power contacts. In addition, it is also conceivable to carry out the procedure only when the resistance value has not changed within a predefined time window.

In a further development of the invention, it is provided that a DC component and an AC component of the voltage difference are determined by a continuous-time or discrete-time repetition of steps e and f and subsequent filtering, in particular low-pass filtering. Based on the determined AC component of the voltage difference, mechanical vibration of the electrical device can therefore be detected. With particular advantage, this method can also be used to draw conclusions about the rotational speed of an electric motor or the number of strokes of an impact mechanism of an electrical device designed as an electrical load.

Based on the voltage difference calculated in step f, a first contact resistance value between the first power contacts of the first electromechanical interface of the exchangeable energy store and the further electromechanical interface of the electrical device can also be calculated as a function of the flowing charging or discharging current. The first contact resistance value can provide information as to whether at least one of the first power contacts of the electromechanical interfaces is soiled or worn.

By means of a current pulse applied to a second power contact of the electromechanical interfaces, a battery voltage change can be measured across the first and second power contacts and a virtual internal resistance value of the exchangeable energy store can be calculated on the basis of the measured battery voltage change. The second power contact is designed as an electrical contact of the electromechanical interfaces to which a supply potential can be applied. The calculation of the virtual internal resistance value is based on the assumption that the two contact resistances between the first and second power contacts of the electromechanical interfaces are symmetrically distributed.

If a nominal internal resistance value of the exchangeable energy store is known to the electrical device—for example, because it has been stored in a storage system of the control or regulation unit of the electrical device and read out via the coding resistor or because it has been transmitted from the exchangeable energy store to the electrical device by means of corresponding wireless communication interfaces—, a second contact resistance value between the second power contacts of the electromechanical interfaces can be calculated such that the nominal internal resistance value and the first contact resistance value are subtracted from the virtual internal resistance value of the exchangeable energy store. In this way, wear or soiling of the second power contacts of the electromechanical interfaces can also be detected.

In a further embodiment of the invention, it is provided that the electrical device reduces or interrupts the charging or discharging current when the first and/or the second contact resistance value exceed a first threshold value. If the charging or discharging current is reduced, it is possible to continue an ongoing charging or discharging process while observing certain safety measures. For example, an electrical load can continue to be operated at reduced power, while a charging device charges the exchangeable energy store more slowly or up to a reduced limit value. Interrupting the charging or discharging current, on the other hand, causes the charging or discharging process to end immediately. Correct operation is only possible again when the first and/or second contact resistance value falls below the first threshold value.

In addition, it may be provided that the electrical device interrupts the charging or discharging current if the first and/or second contact resistance value exceeds a second threshold value. In this case, exceeding the first threshold value only causes a reduction in the charging or discharging current. This has the advantage of further increasing the flexibility and security of the system.

A further embodiment of the invention provides that a compensation of the voltage drops at the signal contact or data contacts of the electrical device, a reduction or interruption of the charging or discharging current and/or a detected vibration of the electrical device are indicated to an operator and/or transmitted to an external device, in particular wirelessly. The display can be designed as an HMI (Human Machine Interface) of the electrical device in the form of an LC or OLED display, a simple LED display or corresponding optical means. An acoustic display via a loudspeaker, a PIEZO or similar and/or a haptic display in the form of a vibration motor or similar is also conceivable. A wireless communication interface in the form of a Bluetooth, WLAN or ZigBee connection is particularly suitable for transmitting the data to the external device. However, a mobile connection via GSM, LTE, 5G or similar is also conceivable. The transmission can also be wired via USB or similar. Smartphones, tablets, personal computers, cloud servers or the like can serve as external devices within the sense of the invention.

### EXEMPLARY EMBODIMENTS

### Drawings

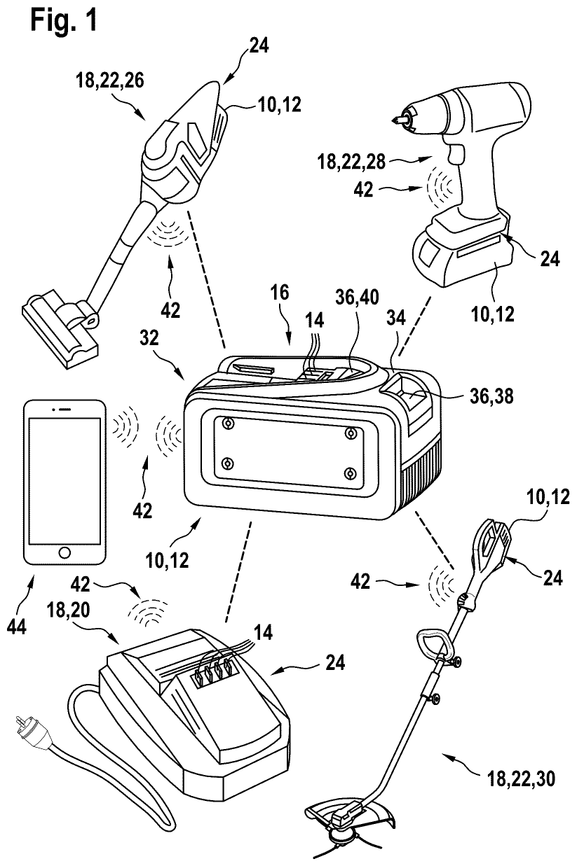

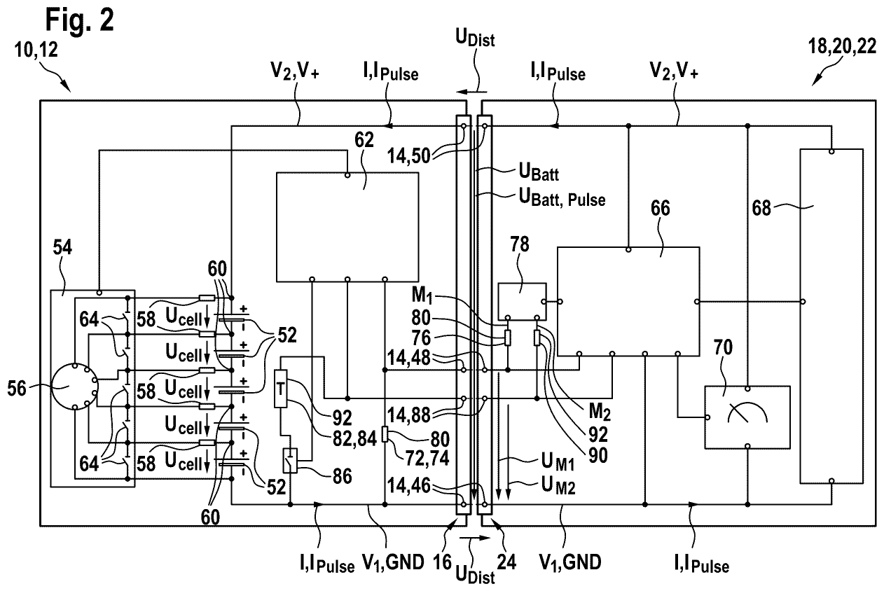

The invention is explained hereinafter with reference to FIGS. 1 and 2 by way of example, wherein identical reference characters in the drawings indicate identical components having an identical function.

### Shown are:

FIG. 1: a system comprising an exchangeable energy store designed as an exchangeable rechargeable battery pack and at least one electrical device connectable to the exchangeable rechargeable battery pack, in particular a charging device and various electrical loads designed as power tools, for charging or discharging the exchangeable rechargeable battery pack in a schematic representation and

FIG. 2: the system shown in FIG. 1 as a block diagram with an exchangeable rechargeable battery pack and an electrical device designed as a charging device.

### DESCRIPTION OF THE EXEMPLARY EMBODIMENTS

FIG. 1 shows a system comprising an exchangeable energy store 12 in the form of an exchangeable rechargeable battery pack 10 with a first electromechanical interface 16 having a plurality of electrical contacts 14 and an electrical device 18, in particular a charging device 20 or an electrical load 22, with a further electromechanical interface 24 having a plurality of electrical contacts 14. FIG. 1 is intended to illustrate that the system according to the invention is suitable, without limiting the invention, for various electrical device 18 operated with exchangeable energy stores 12. By way of example, a battery vacuum cleaner 26, a battery impact wrench 28, and a battery lawn trimmer 30 are shown. However, in the context of the invention, other power tools, measuring devices, gardening equipment, construction equipment, household appliances, entertainment devices or comparable electrical devices operable with an exchangeable energy store 10 may also be considered as electrical loads 22. The number of exchangeable energy stores 12 can also be varied within the system, so that it may well comprise a plurality of exchangeable rechargeable battery packs 10. In the context of the invention, road, rail or air vehicles equipped with accumulators or fuel cells, whose energy stores are only exchangeable by the manufacturer, can also be considered as electrical loads 22. Likewise, the exchangeable energy stores 12 can be designed as non-rechargeable primary cells or the like. In this case, however, the invention is limited purely to the discharging process.

The exchangeable rechargeable battery pack 12 has a housing 32, which has the first electromechanical interface 16 on a first side wall or its upper side 34 for positive and/or non-positive detachable connection to the electromechanical interface 24 of the electrical device 18. In conjunction with the electrical load 22, the first and further electromechanical interfaces 16, 24 are primarily used for discharging and, in conjunction with the charging device 20, for charging the exchangeable rechargeable battery pack 10. The exact design of the first and the further electromechanical interface 16, 24 depends on various factors, such as the voltage class of the exchangeable rechargeable battery pack 10 or the electrical device 18 as well as various manufacturer specifications. For example, three or more electrical contacts 14 may be provided for transferring power and/or data between the exchangeable rechargeable battery pack 12 and the electrical device 18. Mechanical coding is also conceivable, so that the exchangeable rechargeable battery pack 10 can only be operated on certain electrical devices 18.

The exchangeable rechargeable battery pack 10 includes a mechanical locking device 36 for locking the positively and/or non-positive detachable connection of the first electromechanical interface 16 of the exchangeable rechargeable battery pack 10 to the corresponding counter-interface 24 (not shown in detail) of the electrical load 22. The locking device 36 is designed as a spring-loaded pusher 38, which is operatively connected to a locking element 40 of the exchangeable rechargeable battery pack 10. Due to the resilience of the pusher 38 and/or of the locking element 40, the locking device 36 automatically engages when the exchangeable rechargeable battery pack 10 is inserted into the counter-interface 24 of the electrical load 22. If an operator presses the pusher 38 in the direction of insertion, the locking mechanism is released and the operator can remove or push out the exchangeable rechargeable battery pack 10 from the electrical load 22 in the opposite direction to the direction of insertion.

It should be noted that the design of the electromechanical interfaces 16, 24 of the exchangeable rechargeable battery pack 10 and the electrical devices 18 connectable thereto, as well as the associated receptacles for the non-positive and/or positive-locking detachable connection, are not intended to be the subject of the present invention. A person skilled in the art will choose a suitable embodiment for the electromechanical interfaces 16, 24 depending on the power or voltage class of the electrical device 18 and/or the exchangeable rechargeable battery packs 10. The embodiments shown in the drawings are therefore only to be understood by way of example. In particular, electromechanical interfaces 16, 24 with more or fewer than the four electrical contacts 14 shown can also be used.

As already mentioned above, the battery voltage of the exchangeable rechargeable battery pack 10 generally results from a multiple of the individual voltages of the energy storage cells (not shown) as a function of their connection (in parallel or in series). Preferably, the energy storage cells are formed as lithium-based battery cells, e.g., Li-ion, Li-po, Li-metal, or the like. However, the invention can also be applied to exchangeable rechargeable battery packs having Ni—Cd cells, Ni-MH cells, or other suitable cell types.

Via a communication interface 42 of the exchangeable rechargeable battery pack 10 and/or the electrical device 18, which is preferably designed as a radio interface (e.g. Bluetooth, Wi-Fi, NFC, ZigBee, LoRa, GSM, UMTS, LTE, 5G or the like), it is possible for the operator to transmit information about the charging and/or discharging processes of the exchangeable rechargeable battery pack 10 and/or the electrical device 18 to an external device 44, such as a smartphone, tablet, PC, cloud server or the like. It is also possible to read out or control via an app or software installed on the external device 44. It is also conceivable that the exchangeable rechargeable battery pack 10 and the electrical devices 18 exchange data with each other via their respective communication interfaces 42. Alternatively or additionally, the communication interfaces 42 can also be contact-based. For example, transmission can take place via Universal Serial Bus (USB), Lightning, RS232 or via the electrical contacts 14 of the electromechanical interfaces 16, 24. The communication interfaces 42 can be designed as a microprocessor or the like and comprise all the necessary communication technology means, such as a modulator, demodulator, antennas, etc.

FIG. 2 shows the system from FIG. 1 as a block diagram with the exchangeable energy store 12 in the form of an exchangeable rechargeable battery pack 10 on the left-hand side and the electrical device 18 in the form of a charging device 20 on the right-hand side. Exchangeable rechargeable battery pack 10 and charging device 20 have corresponding electromechanical interfaces 16 and 24 with a plurality of electrical contacts 14, wherein a first one of the electrical contacts 14 of the interfaces 16, 24 serves as a power contact 46 to which a first reference potential V₁, preferably a ground potential GND, can be applied and a second one of the electrical contacts 14 of the interfaces 16, 24 serves as a first signal contact or data contact 48.

Via the first power contact 46 and a second power contact 50 to which a second reference potential V₂, preferably a supply potential V₊, can be applied, the exchangeable rechargeable battery pack 10 can be charged by the charging device 20 and discharged by an electrical device 18 designed as an electrical load 22. The phrase “can be applied” is intended to clarify that the potentials V₊ and GND, in particular in the case of an electric load 22 are not permanently present at the power contacts 46, 48, but only after the electromechanical interfaces 16 and 24 have been connected. The same applies to a discharged exchangeable rechargeable battery pack 10 after connection to the charging device 20.

The exchangeable rechargeable battery pack 10 comprises a plurality of energy storage cells 52, which are shown in FIG. 2 as a series circuit but may alternatively or additionally also be operated in a parallel circuit, wherein the series circuit defines the battery voltage of the exchangeable rechargeable battery pack 10 U_{Batt} dropping across the power contacts 50, 46, while a parallel circuit of individual energy storage cells 52 primarily influences the capacitance of the exchangeable rechargeable battery pack 10. As previously mentioned, individual cell clusters consisting of energy storage cells 52 connected in parallel can also be connected in series in order to achieve a specific battery voltage U_{Batt} of the exchangeable rechargeable battery pack 10 with simultaneously increased capacitance. For common Li-ion energy storage cells 52 with a cell voltage U_{Cell} of 3.6 V each, a battery voltage U_{Batt}=V₂−V₁ of 5−3.6 V=18 V drops across the power contacts 50, 46 in the present exemplary embodiment. Depending on the number of energy storage cells 52 connected in parallel in a cell cluster, the capacitance of conventional exchangeable rechargeable battery packs 10 can be up to 12 Ah or more. However, the invention is not dependent on the type, design, voltage, power supply capability, etc. of the energy storage cells 52 used, but can be used for any exchangeable rechargeable battery pack 10 and energy storage cells 52.

A single-cell monitoring (SCM) pre-stage 54 is provided for monitoring the individual energy storage cells 52 connected in series, or the cell clusters of the exchangeable rechargeable battery pack 10. The SCM pre-stage 54 comprises a multiplexer measuring device 56 which, via filter resistors 58, can be connected at a high impedance level to corresponding taps 60 of the poles of the energy storage cells 52 or cell clusters. In order to sense the individual cell voltages, U_{Cell}, the multiplexer measuring device 56 sequentially switches, for example via integrated transistors not shown in more detail, between the individual taps 60 such that it is always connected to a positive and a negative pole of the energy storage cell 52 to be measured or the cell cluster to be measured. In the following, the term “energy storage cells” is also intended to include the cell cluster since the former only influence the capacitance of the exchangeable rechargeable battery pack 10, but are equivalent with regard to the detection of the cell voltages U_{Cell}. In the event of a fault, the filter resistors 58, which are designed at a high impedance level, serve to prevent dangerous heating of the measurement inputs of the multiplexer measuring device 56.

The multiplexer measuring device 56 is switched via a first control or regulation unit 62 integrated in the exchangeable rechargeable battery pack 10. These may also close or open switching elements 64, connected in parallel to the energy storage cells 52, of the SCM pre-stage 54 in order to, in this way, cause a so-called balancing of the energy storage cells 52 to achieve uniform charge and/or discharge states of the individual energy storage cells 52. It is likewise conceivable that the SCM pre-stage 54 passes the measured cell voltages U_{Cell} directly to the first control or regulation unit 62, so that the actual measurement of the cell voltages U_{Cell} is performed directly by the first control or regulation unit 62, for example via corresponding analog-to-digital converters (ADC).

The first control or regulation unit 62 may be formed as an integrated circuit in the form of a microprocessor, ASIC, DSP or the like. However, it is also conceivable that the first control or regulation unit 62 consists of several microprocessors or at least partially of discrete components with corresponding transistor logic. In addition, the first control or regulation unit 62 may comprise a storage system for storing operating parameters of the exchangeable rechargeable battery pack 10, such as the battery voltage U_{Batt}, the cell voltages U_{Cell}, a charging or discharging current I, a current integral, a temperature T or the like.

In addition to the first control or regulation unit 62 in the exchangeable rechargeable battery pack 10, the electrical devices 18 of the system also each have a further control or regulation unit 66, which can be designed to correspond to the first control or regulation unit 62. The first and the further control or regulation unit 62 or 66 can exchange information via the first signal contact or data contact 48 of the two electromechanical interfaces 16, 24, preferably digitally.

The further control or regulation unit 66 of the charging device 20 controls power electronics 68 connected to the first and second power contacts 46, 50 of the further electromechanical interface 24, via which the exchangeable rechargeable battery pack 10 inserted into the charging device 20 can be charged with the charging current I. For this purpose, the charging device 20 or the power electronics 68 is provided with a mains connection not shown, wherein the power electronics 68 converts the grid voltage of the mains connection into the required battery voltage U_{Batt}. For this purpose, the power electronics 68 has a power supply unit, in particular a switched-mode power supply unit, including filtering and rectification in a known manner. The battery voltage U_{Batt} applied to the power contacts 46, 50 can be measured via a voltage measuring device 70 in the charging device 20 and evaluated by the further control or regulation unit 66. The voltage measuring device 70 can also be fully or partially integrated in the control or regulation unit 66, for example in the form of an integrated ADC.

So that the charging device 20 can identify the exchangeable rechargeable battery pack 10 and, if necessary, release it for charging, the exchangeable rechargeable battery pack 10 has a first invariable resistor 74 in the form of a coding resistor 72, which is connected on one side to the ground potential GND applied to the first power contact 46 and on the other side to the first signal contact or data contact 48 of the first electromechanical interface 16 of the exchangeable rechargeable battery pack 10. Accordingly, the charging device 20 also has a first invariable resistor 76, which is connected on the one hand to the first signal contact or data contact 48 of the further electromechanical interface 24 of the charging device 20 and on the other hand to a voltage regulator 76. Via the voltage regulator 78, the further control and regulation unit 66 of the charging device 20 can apply a first measurement signal M₁, for example in the form of a measurement current, to the first signal contact or data contact 48. The two first resistors 74, 76 of the exchangeable rechargeable battery pack 10 and the charging device 20 form a first voltage divider 80 via the first signal contact or data contacts 48 of the interconnected electromechanical interfaces 16, 24. Thus, the first signal contact or data contacts 48 act as a center tap of the first voltage divider 80. The first measurement signal M₁ causes a first voltage drop U_{M1} across the coding resistor 72, which can be evaluated at the first signal contacts or data contacts 48 by the further control or regulation unit 66 of the charging device 20 such that the further control or regulation unit 66 calculates a resistance value of the coding resistor 72 and compares it with a resistance value stored in its storage system. For example, an analog-to-digital converter (ADC) integrated in the further control or regulation unit 66 can be used to evaluate the first voltage drop U_{M1}. Alternatively, this can also be formed separately from the control or regulation unit 66.

If the calculated resistance value and the resistance value stored in the storage system match, the charging device 20 enables the charging process and charges the exchangeable rechargeable battery pack 10 according to the operating parameters stored in a look-up table, in particular the charging current I or the battery voltage U_{Batt}. Additionally or alternatively, it is possible for the exchangeable rechargeable battery pack 10 to monitor and evaluate the first measurement signal M₁ at the first signal contact or data contacts 48 via the first control or regulation unit 62 in order to influence the charging process if necessary. The first and the further control or regulation unit 62, 66 can also exchange information or data, for example in the form of the operating parameters and/or possibly further measured values, directly via the first signal contact or data contacts 48 for further processing.

Similarly, an electrical device 18 designed as an electrical load 22 can enable the discharge process of the exchangeable rechargeable battery pack 10 via a corresponding coding resistor 72 or a further invariable resistor (not shown) connected to the ground potential GND. For this purpose, the control or regulation unit 66 of the electrical load 22 queries the resistance value of the coding resistor 72 or the further invariable resistor via the signal contact or data contact 48 or a further signal contact or data contact (not shown) of the further interface 24 and compares it with a value stored in its storage system. If the values do not match, the discharge process of the exchangeable rechargeable battery pack 10 is aborted or not allowed, so that the electrical load 22 cannot be put into operation. If the values match, an operator can put the electrical load 22 into operation. With particular advantage, this allows operation of exchangeable rechargeable battery packs 10 of different power classes with the same electromechanical interfaces 16 or 24. It goes without saying that, in the case of an electrical load 22, the power electronics 68 contained in the charging device 20 is designed as a drive unit, for example as an electric motor (possibly with corresponding upstream power electronics) or another energy-consuming unit, which is controlled, for example, via a power output stage integrated in the power electronics 68 by means of a pulse-width modulated signal (PWM). The design of such power electronics 68 will not be discussed further here, as it is sufficiently known to the person skilled in the art for a wide variety of types of electrical loads 22 and, moreover, is not of decisive importance for the invention as such.

By means of a second variable resistor 84 arranged in the exchangeable rechargeable battery pack 10 and designed as a temperature resistor 82, a temperature T of the exchangeable rechargeable battery pack 10 or of the energy storage cells 52 can be measured and evaluated by the further control or regulation unit 66 of the charging device 20. The temperature resistor 82 is preferably designed as an NTC and is in close thermal contact with at least one of the energy storage cells 52. Furthermore, the temperature resistor 82 is connected on the one hand via a switching element 86 integrated in the exchangeable rechargeable battery pack 10, for example a bipolar transistor or MOSFET, to the ground potential GND applied to the first power contact 46 and on the other hand to a contact 14 of the first electromechanical interface 16 of the exchangeable rechargeable battery pack 10, which is designed as a second signal contact or data contact 88. Correspondingly, a second signal contact or data contact 88 is provided in the further electromechanical interface 24 of the charging device 20, which is connected to the further control or regulation unit 66. The further control or regulation unit 66 can apply a second measurement signal M₂ to the second signal contact or data contact 88 via a second invariable resistor 90, which is connected on the one hand to the second signal contact or data contact 88 and on the other hand to the voltage regulator 78. Analogous to the first measurement signal M₁, the second measurement signal M₂ can be a measurement current which causes a second voltage drop U_{M2} across the temperature resistor 82 and drops at a center tap of a second voltage divider 92 formed from the two second resistors 82 and 90 and formed by the second signal or data contact 88. By means of the second voltage drop U_{M2} and the measuring current, a resistance value of the temperature resistor 82 can be calculated and compared with a resistance value stored in a look-up table of the further control or regulation unit 66 in order to derive or detect the current temperature T of the exchangeable rechargeable battery pack 10 or the energy storage cells 52.

Furthermore, within the exchangeable rechargeable battery pack 10, the second signal contact or data contact 88 of the first electromechanical interface 16 is connected to the first control or regulation unit 62. In this way, the first control or regulation unit 62 can, on the one hand, directly detect the temperature T and, on the other hand, determine whether the temperature T measured by the temperature resistor 82 has been queried by the further control or regulation unit 60 of the charging device 20. If this is the case, the first control or regulation unit 62 is automatically switched from a sleep mode to an operating mode. If no such query is made, the sleep mode of the first control or regulation unit 62 allows significantly longer idle and storage times for the exchangeable rechargeable battery pack 10 due to the reduced quiescent current.

The temperature is detected in an electrical device 18 designed as an electrical load 22 in the same way as described above for the charging device 20, with the difference that it is not the charging process but the discharging process of the exchangeable rechargeable battery pack 10 that can be influenced in the electrical load 22.

As described at the beginning, when charging or discharging the exchangeable rechargeable battery pack 10 at the contacts 14, in particular at the power contacts 46, 50, of the electromechanical interfaces 16, 24 of the exchangeable rechargeable battery pack 10 and/or the electrical device 18, an undesirable voltage drop U_{Dist} can occur due to any contact resistances, which depends on the respective charging or discharging current I. The voltage drop U_{Dist} can lead to a distortion of the measurement signals M₁, M2 provided via the signal contact or data contacts 48, 88 in the electrical load 22 or in the charging device 20 if the measurement signals M₁, M₂ relate, for example, to the ground potential GND of the first power contact 46 that is operatively connected to it. In addition, increasing wear or soiling of the electrical contacts 14 increases their contact resistance and thus also the resulting voltage drop U_{Dist}, which can ultimately lead to an impairment of the function of the electrical device 18 or the exchangeable rechargeable battery pack 10. In this context, “operatively connected” should be understood to mean that there is an electrical connection between the corresponding contacts 14 such that, for example, a measurement signal in the form of a measurement current introduced into a contact 14 also flows via the contact 14 that is operatively connected to it.

The following process steps are therefore provided for determining the contact resistance value R_{Dist}:
a. connecting the first electromechanical interface 16 of the exchangeable energy store 12 to the further electromechanical interface 24 of the electric device 18,
b. applying the first measurement signal M1 to the first signal contact or data contact 48 of the further electromechanical interface 24 of the electrical device 18, without a charging or discharging current I flowing,
c. detecting a first voltage drop UM1 between the first signal contact or data contact 48 and the first power contact 46 of the further electromechanical interface 24 of the electrical device 18 operatively connected to the first signal contact or data contact 48,
d. additionally, applying a charging or discharging current I to the power contact 46 of the further electromechanical interface 24 of the electrical device 18,
e. detecting again a first voltage drop UM1 between the first signal contact or data contact 48 and the first power contact 46 of the further electromechanical interface 24 of the electrical device 18, and
f. calculating a voltage difference U_{Dist} between the first voltage drops U_{M1} detected in step c and step e.

Based on the voltage difference U_{Dist} calculated in step f, corresponds to the aforementioned undesired voltage drop U_{Dist} a first contact resistance value R_{Dist1} between the first power contacts 46 of the electromechanical interfaces 16, 24 can then be calculated as a function of the flowing charging or discharging current I. The first contact resistance value R_{Dist1} provides an indication of whether at least one of the first two power contacts 46 of the electromechanical interfaces 16, 24 is soiled or worn.

If a current pulse I_{Pulse} is applied to the second power contact 50 of the electromechanical interfaces 16, 14, a battery voltage change U_{Batt}, Pulse can be measured across the first and second power contacts 46, 50, on the basis of which a virtual internal resistance value R_{I,virt} of the exchangeable rechargeable battery pack 10 can be calculated. The calculation of the virtual internal resistance value R_{I,virt} is initially based on the assumption that the first and second power contacts 46, 50 each have the same contact resistance values R_{Dist1}, R_{Dist2} and are therefore symmetrically distributed. The virtual internal resistance value R_{I,virt} can then be used as the basis for calculating the second contact resistance value R_{Dist2} between the second power contacts 50 of the electromechanical interfaces 16, 24 such that a nominal internal resistance value R_{I} of the exchangeable rechargeable battery pack 10 and the first contact resistance value R_{Dist1} are subtracted from the virtual internal resistance value R_{I,virt} known in the electrical device 18:

$${R}_{Dist 2} = {R}_{I , virt} - ( {R}_{I} + {R}_{Dist 1} )$$

In this way, wear or soiling of the second power contacts 50 of the electromechanical interfaces 16, 24 can also be detected.

The electrical device 18 can reduce or interrupt the charging or discharging current I if the first and/or the second contact resistance value R_{Dist1}, R_{Dist2} exceed a first threshold value S₁. If the charging or discharging current I is reduced, it is therefore possible to continue an ongoing charging or discharging process while observing certain safety measures. For example, an electrical device 18 designed as an electrical load 22 can continue to be operated with reduced power, while a charging device 20 charges the exchangeable rechargeable battery pack 10 more slowly or up to a reduced limit value. Interrupting the charging or discharging current I, on the other hand, causes the charging or discharging process to end immediately. Proper operation is only possible again when the first and/or the second contact resistance value R_{Dist1}, R_{Dist2} fall below the first threshold value S₁, for example after cleaning or replacement of the related contacts 14.

To increase the flexibility and safety of the system, it can also be provided that the electrical device 18 can also interrupt the charging or discharging current I if the first and/or second contact resistance values R_{Dist1}, R_{Dist2} exceed a second threshold value S₂. In this case, exceeding the first threshold value S₁ only causes a reduction in the charging or discharging current I.

Due to the operative connection between the signal and data contacts 48, 88 and the first power contact 46, the first contact resistance R_{Dist1} between the first power contacts 46 of the interconnected electromechanical interfaces 16, 24 results in a distortion of the voltage drops UM₁, U_{M2} measured in the electrical device 18, which can lead to a false detection of the coding resistor 72 and the temperature T. Using the voltage difference U_{Dist} calculated in step f above, it is therefore possible to compensate for the voltage drops U_{M1}, U_{M2} caused by the measurement signals M₁, M₂ such that the calculated voltage difference U_{Dist} is subtracted from them:

$$\begin{matrix}{U}_{M , comp 1} = {U}_{M 1} - {U}_{Dist} \\ {U}_{M , comp 2} = {U}_{M 2} - {U}_{Dist}\end{matrix}$$

It is particularly advantageous if, in the case of a plurality of measurement signals Mₙ, a measurement signal Mₓ is always used to calculate the voltage difference U_{Dist} in step f, the voltage drop U_{Mx} of which is detected using an invariable resistor 74 of the exchangeable rechargeable battery pack 10, in particular a coding resistor 74 or a comparable resistor with a fixed resistance value. This has the advantage that the calculated voltage difference U_{Dist} is independent of the variables influencing the resistance value, as would be the case, for example, with the variable resistor 84 designed as a temperature resistor 82 as a result of temperature fluctuations due to heating or cooling. In the present exemplary embodiment according to FIG. 2, it is therefore expedient to calculate the voltage difference U_{Dist} in step f on the basis of the first measurement signal M₁, since this is based on the invariable resistor 72, in order then to compensate both the first voltage drop U_{M1} and the second voltage drop U_{M2}, which is dependent on the variable resistor 82, by means of the calculated voltage difference U_{Dist}.

A continuous-time or discrete-time repetition of steps e and f and subsequent filtering, in particular low-pass filtering, can be used to determine a DC component and an AC component of the voltage difference U_{Dist}. Based on the determined AC component of the voltage difference U_{Dist}, mechanical vibrations of the electrical device 18 can be derived, from which in turn conclusions can be drawn about the rotational speed of an electric motor or a number of strikes of a striking mechanism of an electrical device 18 designed as an electrical load 22. This makes it possible, for example, to check the plausibility of any existing sensor readings. Conversely, the determined AC component can also be used to calculate estimated values for electrical devices 18 that do not have a corresponding sensor system.

A compensation of the voltage drops U_{M1}, U_{M2} at the signal contacts or data contacts 48, 88 of the electrical device 18, a reduction or interruption of the charging or discharging current I and/or a detected vibration of the electrical device 18 can be displayed to the operator and/or transmitted to the external device 44, via the respective communication interfaces 42. In addition to wireless transmission, contact-based transmission, for example via the power contacts 46, 50 via powerline communication or via at least one of the signal contact or data contacts 48, 88, can also be used as an alternative or supplement.

The display can be designed as an HMI (Human Machine Interface) of the electrical device 18 in the form of an LC or OLED display, a simple LED display or corresponding optical means. An acoustic display via a loudspeaker, a PIEZO or similar and/or a haptic display in the form of a vibration motor or similar is also conceivable.

Finally, it should be noted that the exemplary embodiments shown are not limited to FIGS. 1 and 2, nor to the number and type of exchangeable rechargeable battery pack 10 and electrical devices 18 shown therein. The same applies to the number of energy storage cells 52 and the associated design of the multiplexer measuring device 56. In addition, the embodiments of the interfaces 16, 24 and the number of their contacts 14 shown are only to be understood by way of example. It should also be noted that the term “first” is not to be interpreted such that there must necessarily be other corresponding features. Rather, it is intended to distinguish these features if they are optionally designed in a plurality.

1. A method for charging or discharging an exchangeable energy store with an electrical device, comprising:
connecting a first electromechanical interface of the exchangeable energy store to a further electromechanical interface of the electric device;
applying a first measurement signal to a first signal or data contact of the further electromechanical interface, without a charging or discharging current flowing;
detecting a first voltage drop between the first signal or data contact and a first power contact of the further electromechanical interface operatively connected to the first signal or data contact;
applying a charging or discharging current to the power contact of the further electromechanical interface;
detecting a further first voltage drop between the first signal or data contact and the first power contact of the further electromechanical interface; and
calculating a voltage difference between the first voltage drop and the further first voltage drop.

2. The method according to claim 1, further comprising:
compensating the first voltage drop at the first signal or data contact using the calculated voltage difference.

3. The method according to claim 2, further comprising:
applying a second measurement signal to at least one second signal or data contact of the further electromechanical interface;
measuring a second voltage drop at the at least one second signal or data contact of the electrical device via the at least one second measurement signal, and
compensating the second voltage drop using the calculated voltage difference.

4. The method according to claim 1, further comprising:
determining a DC component and an AC component of the voltage difference via a continuous-time or discrete-time repetition of the detecting of the further first voltage and the calculating of the voltage difference and subsequent low-pass filtering.

5. The method according to claim 4, further comprising:
detecting a mechanical vibration of the electrical device based on the determined AC component of the voltage difference.

6. The method according to claim 1, further comprising:
calculating a first contact resistance value between the first power contacts of the first electromechanical interface and the further electromechanical interface based on the calculated voltage difference as a function of the flowing charging or discharging current.

7. The method according to claim 6, further comprising:
measuring a battery voltage change across the first and second power contacts by applying a current pulse to a second power contact of the electromechanical interfaces; and
calculating a virtual internal resistance value of the exchangeable energy store based on the measured battery voltage change.

8. The method according to claim 7, further comprising:
calculating a second contact resistance value between the second power contacts of the electromechanical interfaces by subtracting a nominal internal resistance value of the exchangeable energy store known in the electrical device and a first transition contact resistance value from the virtual internal resistance value of the exchangeable energy store.

9. The method according to claim 8, further comprising:
with the electrical device, reducing or interrupting the charging or discharging current when at least one of the first and second contact resistance values exceeds a first threshold value.

10. The method according to claim 8, further comprising:
with the electrical device, interrupting the charging or discharging current when at least one of the first and second contact resistance values exceeds a second threshold value.

11. The method according to claim 3, further comprising:
indicating to an operator and/or wirelessly transmitting to an external device the compensation of the voltage drops at the first and second signal or data contacts of the electrical device.

12. A system for carrying out the method according to claim 1, comprising:
an electrical energy store with a first electromechanical interface having a plurality of electrical contacts; and
an electrical device with a control or regulation unit and a further electromechanical interface having a plurality of electrical contacts,
wherein in each case a first one of the electrical contacts of the electromechanical interfaces is designed as a first signal or data contact and in each case a second of the electrical contacts of the electromechanical interfaces is designed as a first power contact configured for application of a first reference potential
wherein the electrical device and the exchangeable energy store each have at least one first resistor configured to form a first voltage divider connected to the first power contacts via the first signal or data contacts when the electromechanical interfaces are connected.

13. The system according to claim 12, wherein the at least one first resistor of the exchangeable energy store is designed as an invariable resistor or as a variable resistor, and the at least one first resistor of the electrical device is designed as an invariable resistor.

14. The system according to claim 12, wherein in each case a third electrical contact of the electrical contacts of the electromechanical interfaces is designed as a second signal or data contact, and the electrical device and the exchangeable energy store each have at least one second resistor configured to form a second voltage divider connected to the first power contacts via the second signal or data contacts when the electromechanical interfaces are connected.

15. The system according to claim 14, wherein the at least one first resistor of the exchangeable energy store is designed as an invariable resistor, the at least one second resistor of the exchangeable energy store is designed as a variable resistor, and the at least one first and the at least one second resistor of the electrical device are each designed as an invariable resistor.

16. The method according to claim 1, wherein the exchangeable energy store is an exchangeable rechargeable battery pack, and the electrical device is a charging device or an electrical load.

17. The method according to claim 10, further comprising:
indicating to an operator and/or wirelessly transmitting to an external device the reduction or interruption of the charging or discharging current and/or the detected vibration of the electrical device.

18. The system according to claim 12, wherein the exchangeable energy store is an exchangeable rechargeable battery pack, and the electrical device is a charging device or an electrical load.

19. The system according to claim 13, wherein the at least one first resistor of the exchangeable energy store is designed as an invariable coding resistor or a variable temperature resistor.

20. The system according to claim 15, wherein the at least one first resistor of the exchangeable energy store is designed as an invariable coding resistor.
